(19) United States
(12) Patent Application Publication
(10) Pub. No.: US 2019/0107559 A1
(43) Pub. Date: Apr. 11, 2019

(54) INPUT BUFFER AND NOISE CANCELLATION METHOD THEREOF

(71) Applicant: INDUSTRIAL TECHNOLOGY RESEARCH INSTITUTE, Hsin-chu (TW)

(72) Inventors: CHING-FENG LEE, Zhubei City (TW); JIN-FA CHANG, Miaoli County (TW)

(21) Appl. No.: 15/848,283

(22) Filed: Dec. 20, 2017

(30) Foreign Application Priority Data
Oct. 11, 2017 (TW) 106134786

(51) Int. Cl. G01R 1/18; G01R 31/00

(52) U.S. Cl. CPC G01R 1/18; G01R 31/001

(57) ABSTRACT

An input buffer is provided, which may include a noise sensor, a first follower and a subtractor. The common terminal of the first follower may be coupled to the noise sensor; a first bias current source may be coupled to the output of the first follower to generate a first noise current. The subtractor may be coupled to the first follower and the noise sensor. The noise sensor may sense the first noise current and then generate a noise cancellation current via the subtractor in order to cancel the noise generated by the first noise current.

### CROSS REFERENCE TO RELATED APPLICATION

All related applications are incorporated by reference. The present application is based on, and claims priority from, Taiwan Application Serial Number 106134786, filed on Oct. 11, 2017, the disclosure of which is hereby incorporated by reference herein in its entirety.

### TECHNICAL FIELD

The technical field relates to an input buffer, in particular to an input buffer capable of effectively cancelling noise. The technical field further relates to the noise cancellation method of the input buffer.

### BACKGROUND

For the purpose of reducing the distortion when measuring a device under test (DUT), the front-end circuit of the measurement instrument (e.g. oscilloscope) usually includes an input buffer with high impedance and high isolation. This decreases both the loading effect to DUT and the influence to the electrical characteristics of the measurement instrument.

In general, the circuit of the input buffers with high isolation includes two source followers connected with each other in series. Please refer to FIG. 1, which is a schematic diagram of a currently available input buffer. As shown in FIG. 1, the input buffer 1 includes a first-stage circuit 11 and a second-stage circuit 12; the first-stage circuit 11 includes a first follower M1 and a first bias current source A1; the second-stage circuit 12 includes a second follower M2 and a second bias current source A2.

More specifically, the first bias current source A1 and the second bias current source A2 respectively generate a first noise current Iₙ₁ and a second noise current Iₙ₂; thus, the noise Vₙₜ of the output terminal Vₒᵤₜ of the input buffer 1 can be expressed by Equation (1), as follows:

Vₙₜ²=(Iₙ₁²+I_{nM1}²)z₁²+(Iₙ₂²+I_{nM2}²)z₂² (1)

In Equation (1), Vₙₜ stands for the noise of the output terminal Vₒᵤₜ of the input buffer 1; Iₙ₁ stands for the first noise current of the first bias current source A1; Iₙ₂ stands for the second noise current of the second bias current source A2; I_{nM1} stands for the noise current of the first follower M1 itself; I_{nM2} stands for the noise current of the second follower M2 itself; z₁ stands for the output impedance value of the first follower M1; z₂ stands for the output impedance value of the second follower M2.

In addition, there are also some currently available input buffers adopting the resistor bias circuit or the source degeneration bias circuit in order to further reduce noise.

### SUMMARY

An embodiment of the present disclosure relates to an input buffer, which may include a noise sensor, a first follower and a subtractor. The common terminal of the first follower may be coupled to the noise sensor; a first bias current source may be coupled to the output of the first follower to generate a first noise current. The subtractor may be coupled to the first follower and the noise sensor. The noise sensor may sense the first noise current and then generate a noise cancellation current via the subtractor in order to cancel the noise generated by the first noise current.

Another embodiment of the present disclosure relates to a noise cancellation method applicable to an input buffer, which may include the following steps: sensing a first noise current generated by a first bias current source at the output terminal of a first follower by a noise sensor; converting the first noise current into a noise cancellation current via a subtractor; and cancelling the noise generated by the first noise current by the noise cancellation current.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a first schematic diagram of a currently available input buffer.

FIG. 2 is a circuit diagram of an input buffer in accordance with a first embodiment of the present disclosure.

FIG. 3 is a flow chart of the first embodiment of the present disclosure.

FIG. 4 is a circuit diagram of an input buffer in accordance with a second embodiment of the present disclosure.

FIG. 5A is a circuit diagram of an input buffer in accordance with a third embodiment of the present disclosure.

FIG. 5B is a first schematic diagram of the input buffer of the third embodiment of the present disclosure.

FIG. 5C is a second schematic diagram of the input buffer of the third embodiment of the present disclosure.

FIG. 6 is a circuit diagram of an input buffer in accordance with a fourth embodiment of the present disclosure.

FIG. 7A is a circuit diagram of an input buffer in accordance with a fifth embodiment of the present disclosure.

FIG. 7B is a first schematic diagram of the input buffer of the fifth embodiment of the present disclosure.

FIG. 7C is a second schematic diagram of the input buffer of the fifth embodiment of the present disclosure.

FIG. 8 is a circuit diagram of an input buffer in accordance with a sixth embodiment of the present disclosure.

FIG. 9 is a circuit diagram of an input buffer in accordance with a seventh embodiment of the present disclosure.

FIG. 10 is a circuit diagram of an input buffer in accordance with an eighth embodiment of the present disclosure.

FIG. 11 is a circuit diagram of an input buffer in accordance with a ninth embodiment of the present disclosure.

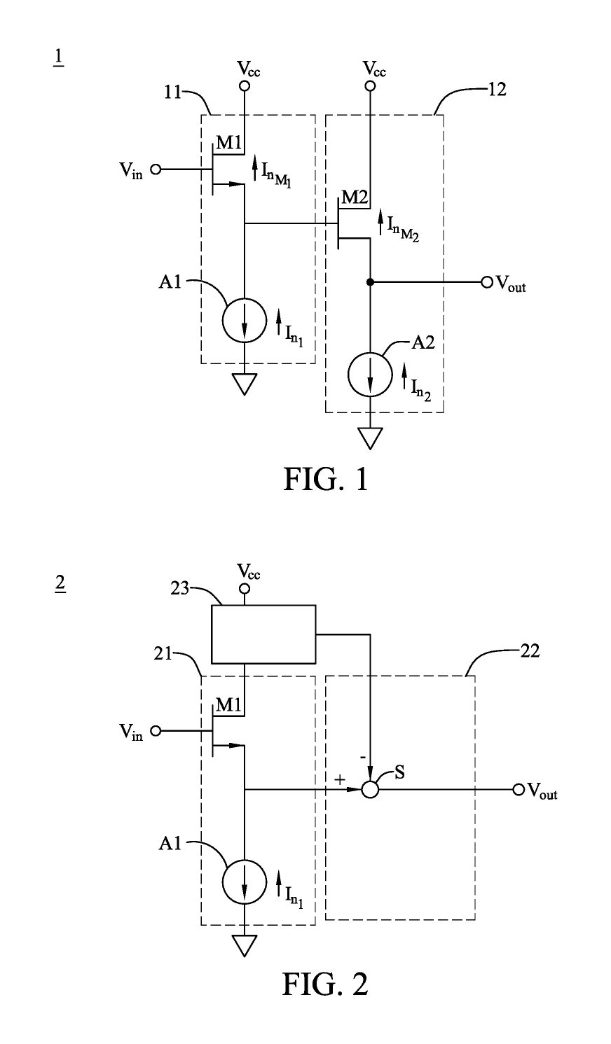

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

FIG. 2 is a circuit diagram of an input buffer of a first embodiment in accordance with the present disclosure. As shown in FIG. 2, the input buffer 2 includes a noise sensor 23, a first-stage circuit 21, and a second-stage circuit 22.

The first-stage circuit 21 includes a first follower M1 and a second bias current source A1. The drain (common terminal) of the first follower M1 is coupled to the noise sensor 23; the first bias current source A1 is coupled to the source (output terminal) of the first follower M1, and generates a first noise current Iₙ₁. The first noise current Iₙ₁ generates a first noise voltage at the source of the first follower M1. In the embodiment, the first follower M1 is a source follower; in another embodiment, the first follower M1 may be an emitter follower.

The second-stage circuit 22 includes a subtractor S. The two output terminals of the subtractor S are coupled to the first follower M1 and the noise sensor 23 respectively.

The noise sensor 23 senses the first noise current Iₙ₁ to generate a first voltage. The subtractor S converts the first voltage into a noise cancellation current, and returns the noise cancellation current to the output terminal of the subtractor S. Thus, the noise cancellation current can generate a noise cancellation voltage at the output terminal of the subtractor S in order to cancel the first noise voltage.

As described above, the input buffer 2 senses the first noise current Iₙ₁ generated by the first bias current source A1 of the first-stage circuit 21, and cancels the first noise current Iₙ₁ via the subtractor S; therefore, the noise outputted by the input buffer 2 can be effectively reduced, so the SNR of the measurement instrument can be improved.

The embodiment just exemplifies the present disclosure and is not intended to limit the scope of the present disclosure. Any equivalent modification and variation according to the spirit of the present disclosure is to be also included within the scope of the following claims and their equivalents.

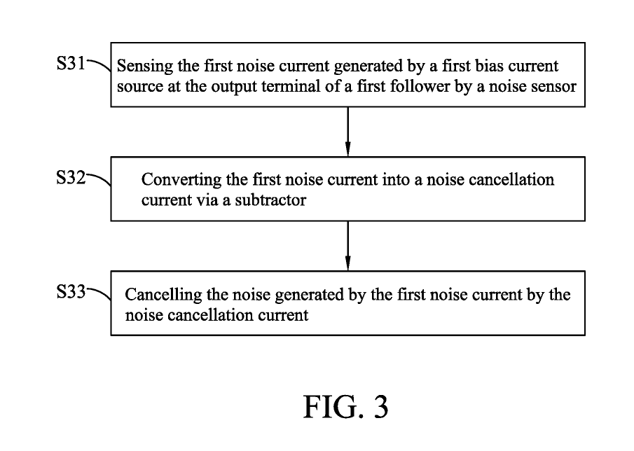

FIG. 3 is a flow chart of the first embodiment in accordance with the present disclosure. As shown in FIG. 3, the noise cancellation method of the input buffer 2 of the embodiment includes the following steps:

Step S31: Sensing the first noise current generated by a first bias current source at the output terminal of a first follower by a noise sensor.

Step S32: Converting the first noise current into a noise cancellation current via a subtractor.

Step S33: Cancelling the noise generated by the first noise current by the noise cancellation current.

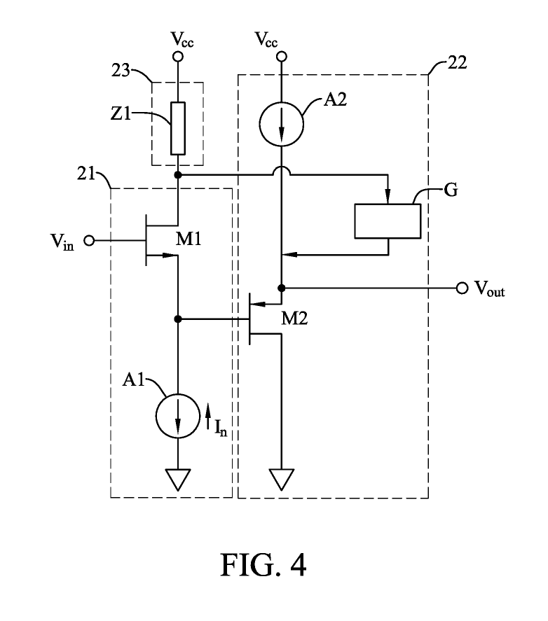

FIG. 4 is a circuit diagram of an input buffer of a second embodiment in accordance with the present disclosure. As shown in FIG. 4, the input buffer 2 includes a noise sensor 23, a first-stage circuit 21, and a second-stage circuit 22.

The noise sensor 23 includes a first impedance Z1. One end of the first impedance Z1 serves as the sensing terminal of the noise sensor 23. The other end of the first impedance Z1 serves as the input terminal of the noise sensor 23, and is coupled to an operating voltage source V_{cc}. In a preferred embodiment, the first impedance Z1 is one or the combination of any two of a resistor, an inductor, and a capacitor.

The first-stage circuit 21 includes a first follower M1 and a first bias current source A1. The first follower M1 is a source follower. The gate (input terminal) of the first follower M1 is coupled to an input voltage source Vᵢₙ. The drain (common terminal) of the first follower M1 is coupled to the sensing terminal of the noise sensor 23. The source (output terminal) of the first follower M1 is coupled to the first bias current source A1.

The second-stage circuit 22 is a subtractor, which includes a second follower M2, a second bias current source A2, and a transconductor G. The second follower M2 is a source follower. The gate (input terminal) of the second follower M2 is coupled to the output terminal of the first follower M1 and a first bias current source A1. The source (output terminal) of the second follower M2 is coupled to the second bias current source A2. The input terminal of the transconductor G is coupled to the sensing terminal of the noise sensor 23, and the drain of the first follower M1. The output terminal of transconductor G is coupled to the source of the second follower M2, and the second bias current source A2.

The first bias current source A1 generates a first noise current Iₙ₁. The first noise current Iₙ₁ generates a first noise voltage at the source of the first follower M1. The noise sensor 23 senses the first noise current Iₙ₁, and generates a first voltage at the sensing terminal of the noise sensor 23.

The transconductor G converts the first voltage into a noise cancellation current, and returns the noise cancellation current to the source of the second follower M2 in order to generate a noise cancellation voltage at the source of the second follower M2.

Therefore, the noise cancellation voltage can completely cancel the first noise voltage by properly selecting the proper first impedance Z1 and the transconductor G.

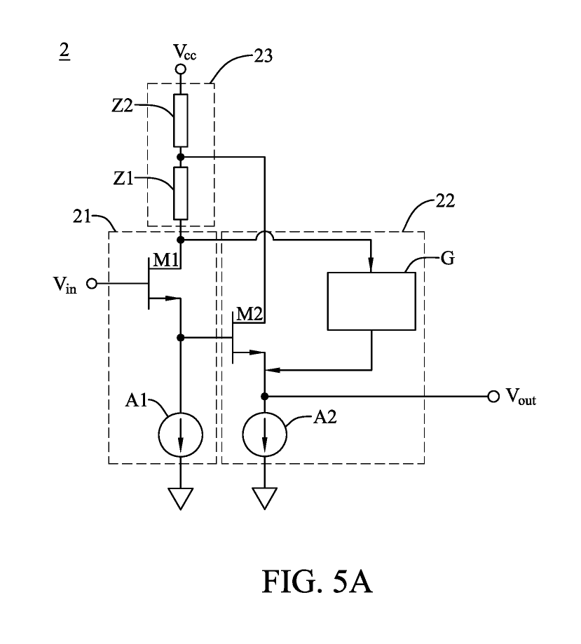

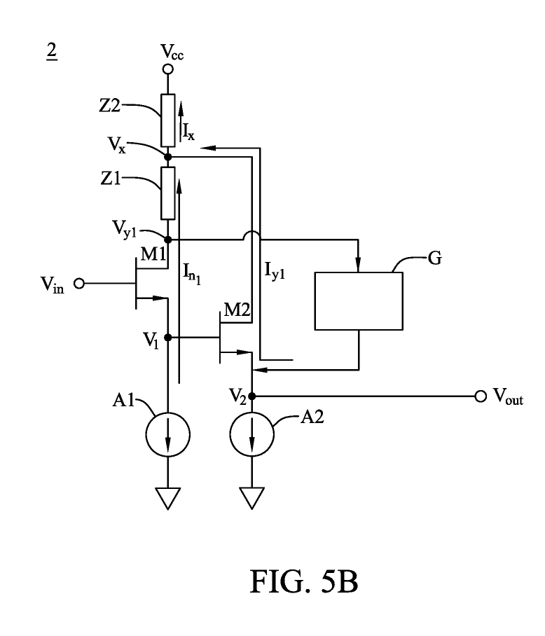

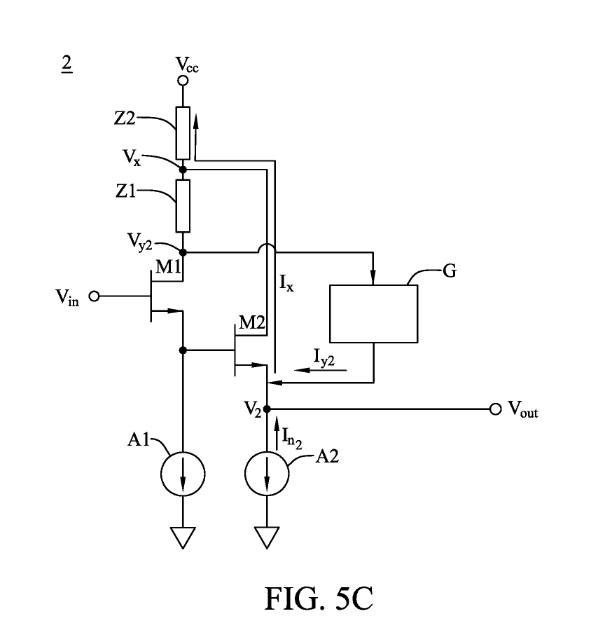

FIG. 5A is a circuit diagram of an input buffer of a third embodiment in accordance with the present disclosure. As shown in FIG. 5A, the input buffer 2 includes a noise sensor 23, a first-stage circuit 21, and a second-stage circuit 22.

The noise sensor 23 includes a first impedance Z1 and a second impedance Z2; the first impedance Z1 is connected to the second impedance Z2 in series. One end of the first impedance Z1 serves as the first sensing terminal of the noise sensor 23. The other end of the first impedance Z1 is coupled to one end of the second impedance Z2, and serves as the second sensing terminal of the noise sensor 23. The other end of the second impedance Z2 serves as the input terminal of the noise sensor 23, and is coupled to an operating voltage source V. In a preferred embodiment, the first impedance Z1 and the second impedance Z2 are one or the combination of any two of a resistor, an inductor, and a capacitor.

The first-stage circuit 21 includes a first follower M1 and a first bias current source A1. The first follower M1 is a source follower. The gate (input terminal) of the first follower M1 is coupled to an input voltage source Vᵢₙ. The drain (common terminal) of the first follower M1 is coupled to the sensing terminal of the noise sensor 23. The source (output terminal) of the first follower M1 is coupled to the first bias current source A1.

The second-stage circuit 22 is a subtractor, which includes a second follower M2, a second bias current source A2, and a transconductor G. The second follower M2 is a source follower. The drain (common terminal) of the second follower M2 is coupled to the second sensing terminal of the noise sensor 23. The gate (input terminal) of the second follower M2 is coupled to the output terminal of the first follower M1 and a first bias current source A1. The source (output terminal) of the second follower M2 is coupled to the second bias current source A2. The input terminal of the transconductor G is coupled to the first sensing terminal of the noise sensor 23, and the drain of the first follower M1. The output terminal of transconductor G is coupled to the source of the second follower M2, and the second bias current source A2.

FIG. 5B is a first schematic diagram of the input buffer of the third embodiment in accordance with the present disclosure. As shown in FIG. 5B, the first bias current source A1 generates a first noise current Iₙ₁, and the first noise current Iₙ₁ generates a first noise voltage V₁ at the source of the first follower M1. The noise sensor 23 senses the first noise current Iₙ₁, and generates a first voltage V_{y1} at the first sensing terminal of the noise sensor 23. The first noise voltage V₁ and the first voltage V_{y1} can be expressed by Equation (2) and Equation (3), as follows:

V₁=Iₙ₁z₁ (2)

V_{y1}=Vₓ+Iₙ₁Z₁ (3)

In Equation (2) and Equation (3), V₁ stands for the first noise voltage; Iₙ₁ stands for the first noise current; V_{y1} stands for the voltage (i.e. the first voltage) of the first sensing terminal of the noise sensor 23; Vₓ stands for the voltage of the second sensing terminal of the noise sensor 23; z₁ stands for the output impedance value of the first follower M1; Z₁ stands for the impedance value of the first impedance Z1.

The voltage Vₓ of the second sensing terminal of the noise sensor 23 can be expressed by Equation (4), as follows:

Vₓ=IₓZ₂ (4)

In Equation (4), Iₓ stands for the current flowing through the second impedance Z2; Z₂ stands for the impedance value of the second impedance Z2.

The transconductor G converts the first voltage V_{y1} into the noise cancellation current I_{y1}, and returns the noise cancellation I_{y1} to the source of the second follower M2 by negative feedback in order to generate a noise cancellation voltage V_{c} at the source of the second follower M2.

The noise cancellation current I_{y1} and the noise cancellation voltage V_{c} can be expressed by Equation (5) and Equation (6), as follows:

I_{y1}=−gₘV_{y1} (5)

V_{c}=I_{y1}z₂ (6)

In Equation (5) and Equation (6), I_{y1} stands for the noise cancellation current; −gₘ stands for the transconductance of the transconductor G; V_{c} stands for the noise cancellation voltage; z₂ stands for the output impedance value of the second follower M2.

According to Equation (5), the current Iₓ flowing through the second impedance Z2 can be expressed by Equation (7), as follows:

Iₓ=Iₙ₁−gₘV_{y1} (7)

According to Equation (3), Equation (4), and Equation (7), the first voltage V_{y1} can be further expressed by Equation (8), as follows:

V_{y1}=(Iₙ₁−gₘV_{y1})Z₂+Iₙ₁Z₁=Iₙ₁(Z₁+Z₂)−gₘZ₂V_{y1}=Iₙ₁(Z₁+Z₂)/(1+gₘZ₂) (8)

According to Equation (5) and Equation (8), the first noise cancellation current I_{y1} can be further expressed by Equation (9), as follows:

I_{y1}=−gₘIₙ₁(Z₁+Z₂)/(1+gₘZ₂) (9)

According to Equation (6) and Equation (9), the noise cancellation voltage V_{c} can be further expressed by Equation (10), as follows:

V_{c}=−gₘIₙ₁(Z₁+Z₂)z₂/(1+gₘZ₂) (10)

As described above, if only the first noise current Iₙ₁ of the first bias current source A1 is considered, the noise voltage Vₙ of the output terminal of the input buffer 2 can be expressed by Equation (11):

Vₙ=V₁+V_{c}=[z₁−gₘ(Z₁+Z₂)z₂/(1+gₘZ₂)]Iₙ₁ (11)

Therefore, the noise voltage Vₙ can be substantially equal to 0 by properly selecting the first impedance Z1, the second impedance Z2, and the transconductor G; in this way, the noise cancellation voltage V_{c} can completely cancel the first noise voltage V₁.

FIG. 5C is a second schematic diagram of the input buffer of the third embodiment in accordance with the present disclosure. As shown in FIG. 5C, the second bias current source A2 generates a second noise current Iₙ₂, and generates a second noise voltage V₂ at the source of the second follower M2. The noise sensor 23 senses the second noise current Iₙ₂, and generates a second voltage V_{y2} at the first sensing terminal of the noise sensor 23. The second noise voltage V₂ and the second voltage V_{y2} can be expressed by Equation (12) and Equation (13), as follows:

V₂=Iₙ₂z₂ (12)

V_{y2}=Vₓ=IₓZ₂ (13)

In Equation (12) and Equation (13), V₂ stands for the second noise voltage; Iₙ₂ stands for the second noise current; V_{y2} stands for the voltage (i.e. the second voltage) of the first sensing terminal of the noise sensor 23; Vₓ stands for the voltage of the second sensing terminal of the noise sensor 23; z₂ stands for the output impedance value of the second follower M2; Z₂ stands for the impedance value of the second impedance Z2.

The noise cancellation current I_{y2} and the noise suppression voltage Vᵣ can be expressed by Equation (14) and Equation (15), as follows:

I_{y2}=−gₘV_{y2} (14)

Vᵣ=I_{y2}z₂ (15)

According to Equation (14), the current Iₓ flowing through the second follower M2 and the second impedance Z2 can be expressed by Equation (16), as follows:

Iₓ=Iₙ₂−gₘV_{y2} (16)

According to Equation (13) and Equation (14), the second voltage V_{y2} can be further expressed by Equation (17), as follows:

V_{y2}=Vₓ=(Iₙ₂−gₘV_{y2})Z₂=Iₙ₂Z₂−gₘZ₂V_{y2}=Iₙ₂Z₂/(1+gₘZ₂) (17)

According to Equation (14) and Equation (17), the noise suppression current I_{y2} can be further expressed by Equation (18), as follows:

I_{y2}=−gₘIₙ₂Z₂/(1+gₘZ₂) (18)

According to Equation (15) and Equation (18), the noise suppression voltage Vᵣ can be further expressed by Equation (19), as follows:

Vᵣ=−z₂gₘIₙ₂Z₂/(1+gₘZ₂) (19)

According to Equation (12) and Equation (19), if only the second noise current Iₙ₂ of the second bias current source A2 is considered, the noise voltage V of the output terminal of the input buffer 2 can be expressed by Equation (20):

Vₙ=V₂+Vᵣ=Iₙ₂z₂/(1+gₘZ₂) (20)

Therefore, the noise suppression voltage Vᵣ can effectively suppress the second noise voltage V₂ by properly selecting the second impedance Z2 and the transconductor G.

The noise of the output terminal Vₒᵤₜ of the input buffer 2 can be expressed by Equation (21):

Vₙₜ²=[z₁−gₘ(Z₁+Z₂)z₂/(1+gₘZ₂)]²Iₙ₁²+(1/1+gₘZ₂)²z₂²Iₙ₂²+I_{nM1}²z₁²+I_{nM2}²z₂² (21)

In Equation (21), Vₙₜ stands for the noise of the output terminal Vₒᵤₜ of the input buffer 2; I_{nM1} stands for the noise current of the first follower M1 itself; I_{nM2} stands for the noise current of the second follower M2 itself.

According to Equation (21), the noise generated by the first noise current Iₙ₁ of the first bias current source A1 can be effectively cancelled, and the noise generated by the second noise current Iₙ₂ of the second bias current source A2 can also be effectively suppressed.

As described above, the input buffer 2 can effectively reduce the noise outputted by the input buffer 2 via two feedback paths and one feed-forward path, so the SNR of the measurement instrument can be significantly increased.

The embodiment just exemplifies the present disclosure and is not intended to limit the scope of the present disclosure. Any equivalent modification and variation according to the spirit of the present disclosure is to be also included within the scope of the following claims and their equivalents.

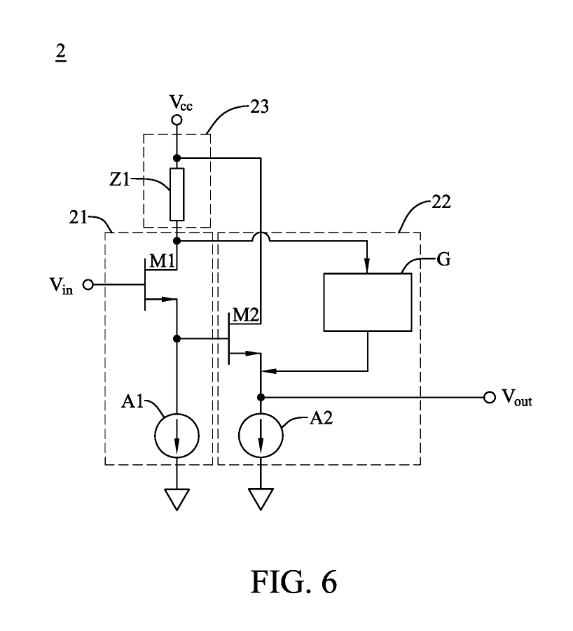

FIG. 6 is a circuit diagram of an input buffer of a fourth embodiment in accordance with the present disclosure. As shown in FIG. 6, the input buffer 2 includes a noise sensor 23, a first-stage circuit 21, and a second-stage circuit 22.

The difference between the embodiment and the previous embodiment is that the noise sensor 23 may include only the first impedance Z1; this circuit structure can still effectively cancel the first noise voltage generated by the first noise current Iₙ₁ of the first bias current source A1. However, the second noise voltage generated by the second noise current Iₙ₂ of the second bias current source A2 cannot be effectively suppressed.

The other components and the functions thereof of the input buffer 2 are similar to those of the third embodiment, so will not be described herein.

The embodiment just exemplifies the present disclosure and is not intended to limit the scope of the present disclosure. Any equivalent modification and variation according to the spirit of the present disclosure is to be also included within the scope of the following claims and their equivalents.

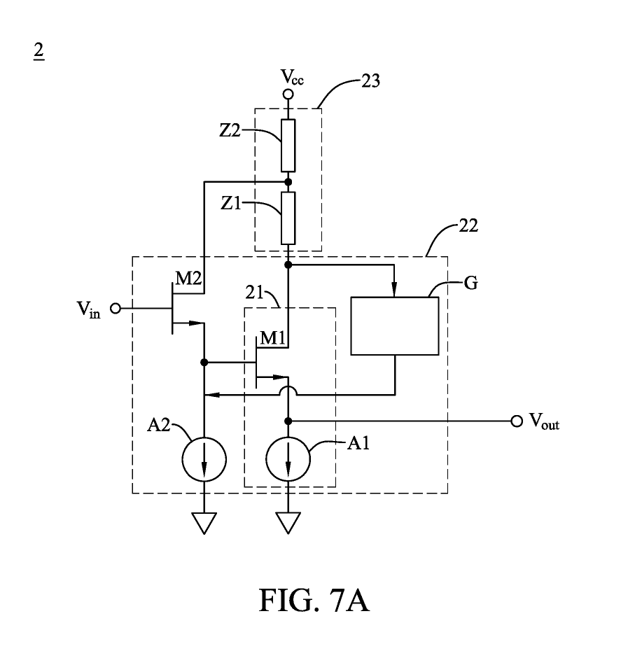

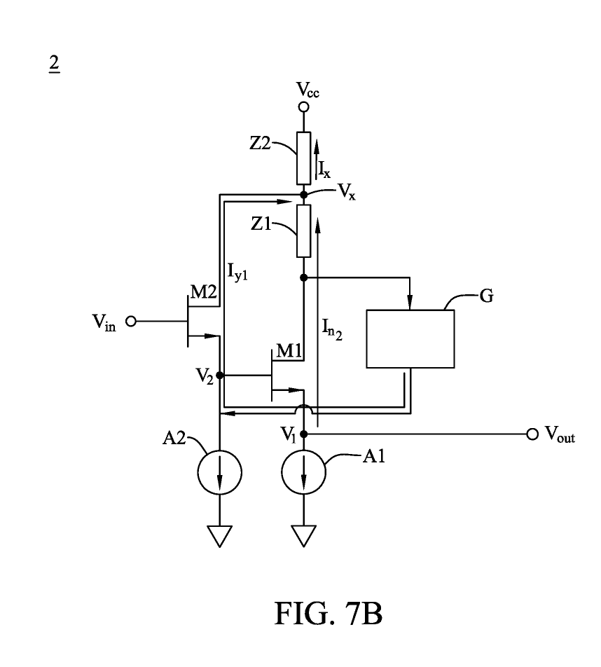

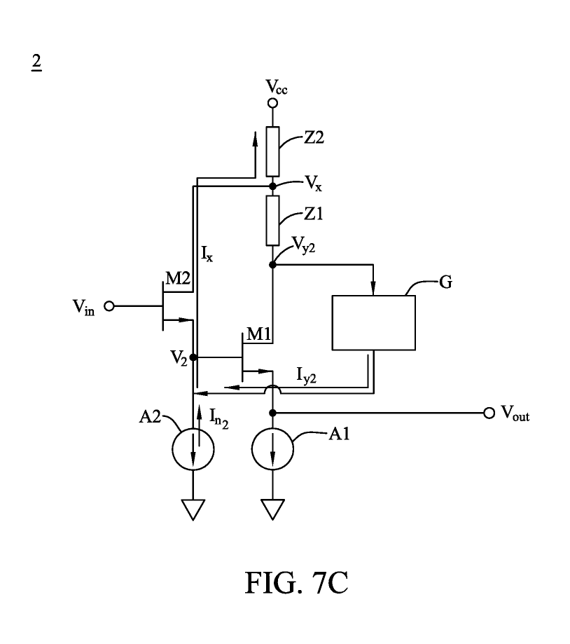

FIG. 7A is a circuit diagram of an input buffer of a fifth embodiment in accordance with the present disclosure. As shown in FIG. 5A, the input buffer 2 includes a noise sensor 23, a first-stage circuit 21, and a second-stage circuit 22.

The noise sensor 23 includes a first impedance Z1 and a second impedance Z2; the first impedance Z1 is connected to the second impedance Z2 in series. One end of the first impedance Z1 serves as the first sensing terminal of the noise sensor 23. The other end of the first impedance Z1 is coupled to one end of the second impedance Z2, and serves as the second sensing terminal of the noise sensor 23. The other end of the second impedance Z2 serves as the input terminal of the noise sensor 23, and is coupled to an operating voltage source V_{cc}.

The first-stage circuit 21 includes a first follower M1 and a first bias current source A1. The first follower M1 is a source follower. The drain (common terminal) of the first follower M1 is coupled to the second sensing terminal of the noise sensor 23. The source (output terminal) of the first follower M1 is coupled to the first bias current source A1.

The second-stage circuit 22 is a subtractor, which includes a second follower M2, a second bias current source A2, and a transconductor G. The second follower M2 is a source follower. The drain (common terminal) of the second follower M2 is coupled to the second sensing terminal of the noise sensor 23. The source (output terminal) of the second follower M2 is coupled to the gate (input terminal) of the first follower M1 and a second bias current source A2. The gate (input terminal) of the second follower M2 is coupled input voltage source Vᵢₙ. The input terminal of the transconductor G is coupled to the drain of the first follower M1 and the first sensing terminal of the noise sensor 23. The output terminal of transconductor G is coupled to the source of the second follower M2, and the second bias current source A2.

FIG. 7B is a first schematic diagram of the input buffer of the fifth embodiment in accordance with the present disclosure. As shown in FIG. 7B, the first bias current source A1 generates a first noise current Iₙ₁, and the first noise current Iₙ₁ generates a first noise voltage V₁ at the source of the first follower M1. The noise sensor 23 senses the first noise current Iₙ₁, and generates a first voltage V_{y1} at the first sensing terminal of the noise sensor 23. The first noise voltage V₁ and the first voltage V_{y1} can be expressed by Equation (22) and Equation (23), as follows:

V₁=Iₙz₁ (22)

V_{y1}=Vₓ+Iₙ₁Z₁ (23)

In Equation (22) and Equation (23), V₁ stands for the first noise voltage; Iₙ₁ stands for the first noise current; V_{y1} stands for the voltage (i.e. the first voltage) of the first sensing terminal of the noise sensor 23; Vₓ stands for the voltage of the second sensing terminal of the noise sensor 23; z₁ stands for the output impedance value of the first follower M1; Z₁ stands for the impedance value of the first impedance Z1.

The voltage Vₓ of the second sensing terminal of the noise sensor 23 can be expressed by Equation (24), as follows:

Vₓ=iₓZ₂ (24)

In Equation (24), Iₓ stands for the current flowing through the second impedance Z2; Z₂ stands for the impedance value of the second impedance Z2.

The transconductor G converts the first voltage V_{y1} into the noise cancellation current I_{y1}, and returns the noise cancellation I_{y1} to the source of the second follower M2 by negative feedback in order to generate a noise cancellation voltage V_{c} at the source of the second follower M2.

The noise cancellation current I_{y1} and the noise cancellation voltage V_{c} can be expressed by Equation (25) and Equation (26), as follows:

I_{y1}=−gₘV_{y1} (25)

V_{c}=i_{y1}z₁ (26)

In Equation (25) and Equation (26), I_{y1} stands for the noise cancellation current; −gₘ stands for the transconductance of the transconductor G; V_{c} stands for the noise cancellation voltage; z₁ stands for the output impedance value of the first follower M1.

According to Equation (25), the current Iₓ flowing through the second impedance Z2 can be expressed by Equation (27), as follows:

Iₓ=Iₙ₁−gₘV_{y1} (27)

According to Equation (23), Equation (24), and Equation (27), the first voltage V_{y1} can be further expressed by Equation (29), as follows:

V_{y1}=(Iₙ₁−gₘV_{y1})Z₂+Iₙ₁Z₁=Iₙ₁(Z₁+Z₂)−gₘZ₂V_{y1}=Iₙ₁(Z₁+Z₂)/(1+gₘZ₂) (28)

According to Equation (25) and Equation (28), the first noise cancellation current I_{y1} can be further expressed by Equation (29), as follows:

I_{y1}=−gₘIₙ₁(Z₁+Z₂)/(1+gₘZ₂) (29)

According to Equation (26) and Equation (29), the noise cancellation voltage V_{c} can be further expressed by Equation (30), as follows:

V_{c}=−gₘIₙ₁(Z₁+Z₂)z₂/(1+gₘZ₂) (30)

As described above, if only the first noise current Iₙ₁ of the first bias current source A1 is considered, the noise voltage Vₙ of the output terminal of the input buffer 2 can be expressed by Equation (31):

Vₙ=V₁+V_{c}=[z₁−gₘ(Z₁+Z₂)z₂/(1+gₘZ₂)]Iₙ₁ (31)

Therefore, the noise voltage Vₙ can be substantially equal to 0 by properly selecting the first impedance Z1, the second impedance Z2, and the transconductor G; in this way, the noise cancellation voltage V_{c} can completely cancel the first noise voltage V₁.

FIG. 7C is a second schematic diagram of the input buffer of the fifth embodiment in accordance with the present disclosure. As shown in FIG. 7C, the second bias current source A2 generates a second noise current Iₙ₂, and generates a second noise voltage V₂ at the source of the second follower M2. The noise sensor 23 senses the second noise current Iₙ₂, and generates a second voltage V_{y2} at the first sensing terminal of the noise sensor 23. The second noise voltage V₂ and the second voltage V_{y2} can be expressed by Equation (32) and Equation (33), as follows:

V₂=Iₙ₂z₂ (32)

V_{y2}=Vₓ=IₓZ₂ (33)

In Equation (32) and Equation (33), V₂ stands for the second noise voltage; Iₙ₂ stands for the second noise current; V_{y2} stands for the voltage (i.e. the second voltage) of the first sensing terminal of the noise sensor 23; Vₓ stands for the voltage of the second sensing terminal of the noise sensor 23; z₂ stands for the output impedance value of the second follower M2; Z₂ stands for the impedance value of the second impedance Z2.

The noise cancellation current I_{y2} and the noise suppression voltage Vᵣ can be expressed by Equation (34) and Equation (35), as follows:

I_{y2}=−gₘV_{y2} (34)

Vᵣ=I_{y2}z₂ (35)

According to Equation (34), the current Iₓ flowing through the second follower M2 and the second impedance Z2 can be expressed by Equation (36), as follows:

Iₓ=Iₙ₂−gₘV_{y2} (36)

According to Equation (33) and Equation (34), the second voltage V_{y2} can be further expressed by Equation (37), as follows:

V_{y2}=Vₓ=(Iₙ₂−gₘV_{y2})Z₂=Iₙ₂Z₂−gₘZ₂V_{y2}=Iₙ₂Z₂/(1+gₘZ₂) (37)

According to Equation (34) and Equation (37), the noise suppression current I_{y2} can be further expressed by Equation (38), as follows:

I_{y2}=−gₘIₙ₂Z₂/(1+gₘZ₂) (38)

According to Equation (35) and Equation (38), the noise suppression voltage Vᵣ can be further expressed by Equation (39), as follows:

Vᵣ=−z₂gₘIₙ₂Z₂/(1+gₘZ₂) (39)

According to Equation (32) and Equation (39), if only the second noise current Iₙ₂ of the second bias current source A2 is considered, the noise voltage Vₙ of the output terminal of the input buffer 2 can be expressed by Equation (40):

Vₙ=V₂+Vᵣ=Iₙ₂z₂/(1+gₘZ₂) (40)

Therefore, the noise suppression voltage Vᵣ can effectively suppress the second noise voltage V₂ by properly selecting the second impedance Z2 and the transconductor G.

The noise of the output terminal Vₒᵤₜ of the input buffer 2 can be expressed by Equation (41):

Vₙₜ²=[z₁−gₘ(Z₁+Z₂)z₂/(1+gₘZ₂)]²Iₙ₁²+(1/1+gₘZ₂)²z₂²Iₙ₂²+I_{nM1}²+I_{nM2}²z₂² (41)

In Equation (41), Vₙₜ stands for the noise of the output terminal Vₒᵤₜ of the input buffer 2; I_{nM1} stands for the noise current of the first follower M1 itself; I_{nM2} stands for the noise current of the second follower M2 itself.

According to Equation (41), the noise generated by the first noise current Iₙ₁ of the first bias current source A1 can be effectively cancelled, and the noise generated by the second noise current Iₙ₂ of the second bias current source A2 can also be effectively suppressed.

As described above, the input buffer 2 can effectively reduce the noise outputted by the input buffer 2 via two feedback paths and one feed-forward path, so the SNR of the measurement instrument can be significantly increased.

The embodiment just exemplifies the present disclosure and is not intended to limit the scope of the present disclosure. Any equivalent modification and variation according to the spirit of the present disclosure is to be also included within the scope of the following claims and their equivalents.

It is worthy to point out that as currently available input buffer cannot effectively cancel the noise, so the noise will directly influence the output terminal of the measurement instrument, so the SNR of the measurement instrument will be significantly reduced. On the contrary, according to the embodiments of the present disclosure, the input buffer can sense the noise generated by the bias current source of the first-stage circuit, and can cancel the above noise via the subtractor; besides, the input buffer can sense the noise generated by the bias current source of the second-stage circuit, and can suppress the above noise via the subtractor. Thus, the noise outputted by the input buffer can be effectively reduced, so the SNR of the measurement instrument can be effectively increased.

Besides, some currently available input buffers adopting the resistor bias circuit or the source degeneration bias circuit with low noise. However, these input buffers need higher operating voltage, so cannot be manufactured by low-voltage IC manufacturing processes; in addition, the bandwidth of the measurement instrument may be significantly influenced by the discrete components used in these input buffers. On the contrary, according to one embodiment of the present disclosure, the input buffer has no the resistor bias circuit or the source degeneration bias circuit, so can be operated at low supply voltage, and can be manufactured by low-noise IC manufacturing processes. Thus, the bandwidth of the measurement instrument will not decrease due to the use of discrete components; therefore, the cost of the measurement instrument can be effectively reduced, and the performance of the measurement instrument can be better.

Moreover, according to one embodiment of the present disclosure, the subtractor of the input buffer not only can effectively reduce noise, but also can be integrated with the second-stage circuit of the input buffer to directly serve as the second-stage circuit of the input buffer, such that the cost of the input buffer can be effectively reduced.

Furthermore, according to one embodiment of the present disclosure, the input buffer can adopt the isolation topology including the circuits of two stages connected in series, so can provide high isolation; accordingly, the performance of the measurement instrument can be further improved.

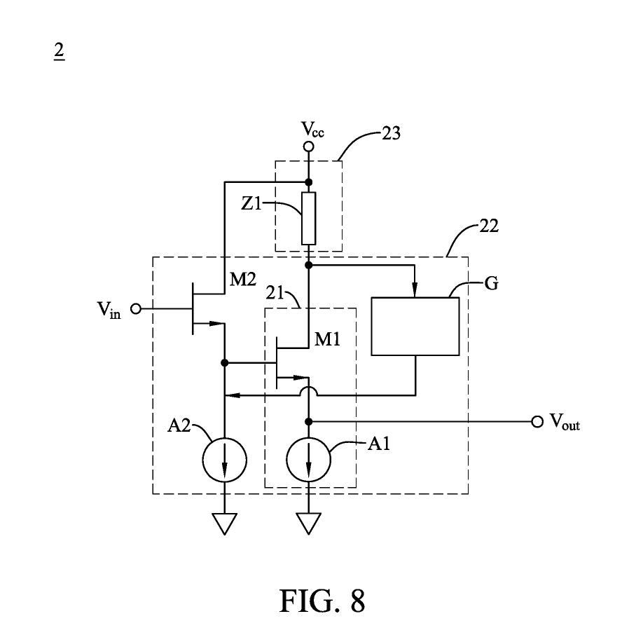

FIG. 8 is a circuit diagram of an input buffer of a sixth embodiment in accordance with the present disclosure. As shown in FIG. 8, the input buffer 2 includes a noise sensor 23, a first-stage circuit 21, and a second-stage circuit 22.

The difference between the embodiment and the previous embodiment is that the noise sensor 23 may include only the first impedance Z1; this circuit structure can still effectively cancel the first noise voltage generated by the first noise current Iₙ₁ of the first bias current source A1. However, the second noise voltage generated by the second noise current Iₙ₂ of the second bias current source A2 cannot be effectively suppressed.

The other components and the functions thereof of the input buffer 2 are similar to those of the fifth embodiment, so will not be described herein.

The embodiment just exemplifies the present disclosure and is not intended to limit the scope of the present disclosure. Any equivalent modification and variation according to the spirit of the present disclosure is to be also included within the scope of the following claims and their equivalents.

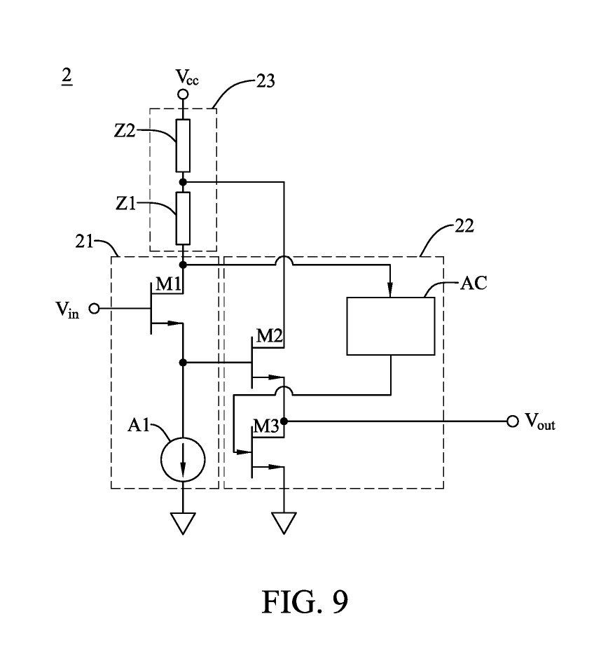

FIG. 9 is a circuit diagram of an input buffer of a seventh embodiment in accordance with the present disclosure. As shown in FIG. 9, the input buffer 2 includes a noise sensor 23, a first-stage circuit 21, and a second-stage circuit 22.

The second-stage circuit 22 includes a second follower M2, an AC coupling AC and a transistor M3. The second follower M2 is a source follower. More specifically, as being integrated with the AC coupling AC, the transistor M3 can serve as not only the second bias current source, but also can serve as the transconductor to provide the transconductance (−gm).

The other components and the functions thereof of the input buffer 2 are similar to those of the second embodiment, so will not be described herein.

The embodiment just exemplifies the present disclosure and is not intended to limit the scope of the present disclosure. Any equivalent modification and variation according to the spirit of the present disclosure is to be also included within the scope of the following claims and their equivalents.

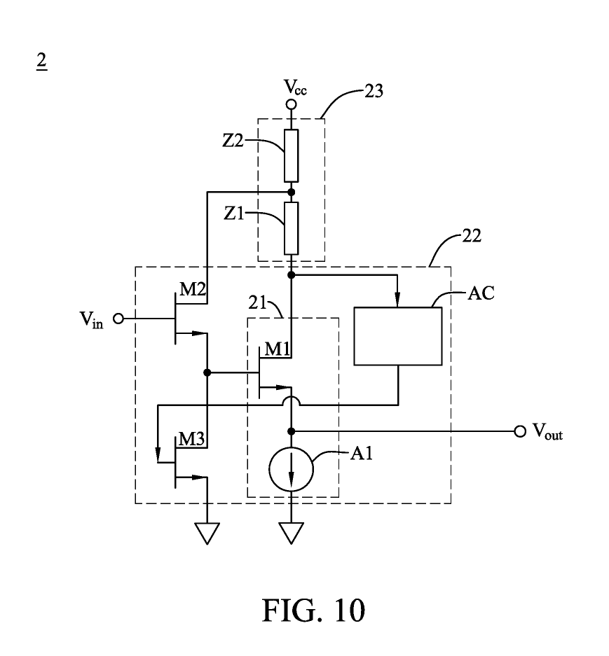

FIG. 10 is a circuit diagram of an input buffer of an eighth embodiment in accordance with the present disclosure. As shown in FIG. 10, the input buffer 2 includes a noise sensor 23, a first-stage circuit 21, and a second-stage circuit 22.

The second-stage circuit 22 includes a second follower M2, an AC coupling AC and a transistor M3. The second follower M2 is a source follower. More specifically, as being integrated with the AC coupling AC, the transistor M3 can serve as not only the second bias current source, but also can serve as the transconductor to provide the transconductance (−gm).

The other components and the functions thereof of the input buffer 2 are similar to those of the third embodiment, so will not be described herein.

The embodiment just exemplifies the present disclosure and is not intended to limit the scope of the present disclosure. Any equivalent modification and variation according to the spirit of the present disclosure is to be also included within the scope of the following claims and their equivalents.

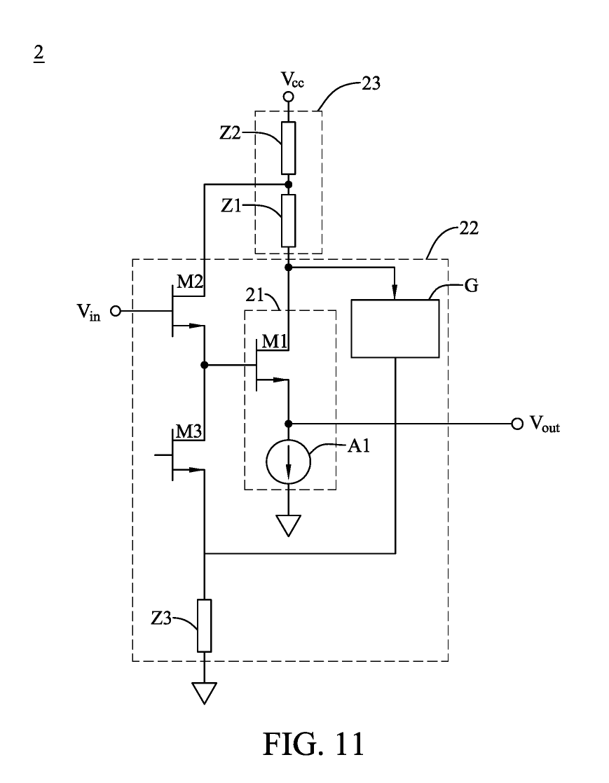

FIG. 11 is a circuit diagram of an input buffer of a ninth embodiment in accordance with the present disclosure. As shown in FIG. 11, the input buffer 2 includes a noise sensor 23, a first-stage circuit 21, and a second-stage circuit 22.

The second-stage circuit 22 includes a second follower M2, a transconductor G, a transistor M3 and a third impedance Z3. The second follower M2 is a source follower. More specifically, the third impedance Z3 can serve as the second bias current source, and the transistor M3 can serve as the isolator in order to increase the isolation of the second bias current source.

The embodiment just exemplifies the present disclosure and is not intended to limit the scope of the present disclosure. Any equivalent modification and variation according to the spirit of the present disclosure is to be also included within the scope of the following claims and their equivalents.

In summation of the description above, according to one embodiment of the present disclosure, the input buffer can sense the noise generated by the bias current source of the first-stage circuit, and can cancel the above noise via the subtractor; thus, the noise outputted by the input buffer can be effectively reduced, so the SNR of the measurement instrument can be effectively increased.

According to one embodiment of the present disclosure, the input buffer can sense the noise generated by the bias current source of the second-stage circuit, and can suppress the above noise via the subtractor; thus, the noise outputted by the input buffer can be effectively reduced, so the SNR of the measurement instrument can be effectively increased.

Also, according to one embodiment of the present disclosure, the subtractor of the input buffer can effectively reduce not only noise, but also can be integrated with the second-stage circuit of the input buffer to directly serve as the second-stage circuit of the input buffer, such that the cost of the input buffer can be effectively reduced.

In addition, according to one embodiment of the present disclosure, the input buffer can be operated at low supply voltage, so can be manufactured by low-voltage IC manufacturing process.

Moreover, according to one embodiment of the present disclosure, the input buffer can be operated at low supply voltage, so the bandwidth of the measurement instrument will not decrease due to the use of discrete components; therefore, the performance of the measurement instrument can be better.

Furthermore, according to one embodiment of the present disclosure, the input buffer can adopt the isolation topology including the circuits of two stages connected in series, so can provide higher isolation; accordingly, the performance of the measurement instrument can be further improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An input buffer, comprising:
a noise sensor;
a first follower, wherein a common terminal of the first follower is coupled to the noise sensor, and a first bias current source is coupled to an output terminal of the first follower to generate a first noise current; and
a subtractor, coupled to the first follower and the noise sensor;
wherein the noise sensor senses the first noise current and generates a noise cancellation current via the subtractor in order to cancel a noise generated by the first noise current.

2. The input buffer of claim 1, wherein the noise sensor senses the first noise current to generate a first voltage, and the subtractor converts the first voltage into the noise cancellation current.

3. The input buffer of claim 2, wherein the first noise current generates a first noise voltage at the output terminal of the first follower, and the noise cancellation current generates a noise cancellation voltage at an output terminal of the subtractor to cancel the first noise voltage.

4. The input buffer of claim 1, wherein the output terminal of the subtractor is coupled to a second bias current source, and the second bias current source generates a second noise current.

5. The input buffer of claim 4, wherein the noise sensor senses the second noise current, and generates a noise suppression current via the subtractor to suppress a noise generated by the second noise current.

6. The input buffer of claim 5, wherein the noise sensor senses the second noise current to generate a second voltage, and the subtractor converts the second voltage into a noise suppression current.

7. The input buffer of claim 6, wherein the second noise current generates a second noise voltage at the output terminal of the subtractor, and the noise suppression current generates a noise suppression voltage at the output terminal of the subtractor to suppress the second noise voltage.

8. The input buffer of claim 5, wherein an input terminal of the noise sensor is coupled to an operating voltage source.

9. The input buffer of claim 8, wherein the noise sensor comprises a first impedance and a second impedance coupled to the first impedance in series.

10. The input buffer of claim 9, wherein one end of the first impedance serves as a first sensing terminal of the noise sensor, the other end of the first impedance is coupled to one end of the second impedance to serve as a second sensing terminal of the noise sensor, and the other end of the second impedance serves as an input terminal of the noise sensor.

11. The input buffer of claim 10, wherein an input terminal of the first follower is coupled to an input voltage source, and the common terminal of the first follower is coupled to the first sensing terminal of the noise sensor.

12. The input buffer of claim 11, wherein the subtractor comprises a second follower and a transconductor.

13. The input buffer of claim 12, wherein a common terminal of the second follower is coupled to the second sensing terminal of the noise sensor, an output terminal of the second follower is coupled to the second bias current source, and an input terminal of the second follower is coupled to the output terminal of the first follower and the first bias current source.

14. The input buffer of claim 13, wherein an input terminal of the transconductor is coupled to the first sensing terminal of the noise sensor and the common terminal of the first follower, and an output terminal of the transconductor is coupled to the output terminal of the second follower and the second bias current source.

15. The input buffer of claim 14, wherein the first follower and the second follower are emitter followers or source followers.

16. The input buffer of claim 10, wherein the common terminal of the first follower is coupled to the first sensing terminal of the noise sensor.

17. The input buffer of claim 16, wherein the subtractor comprises a second follower and a transconductor.

18. The input buffer of claim 17, wherein a common terminal of the second follower is coupled to the second sensing terminal of the noise sensor, an output terminal of the second follower is coupled to an input terminal of the first follower and the second bias current source, and an input terminal of the second follower is coupled to an input voltage source.

19. The input buffer of claim 18, wherein an input terminal of the transconductor is coupled to the common terminal of the first follower and the first sensing terminal of the noise sensor, and an output terminal of the transconductor is coupled to the output terminal of the second follower and the second bias current source.

20. The input buffer of claim 19, wherein the first follower and the second follower are emitter followers or source followers.

21. A noise cancellation method applicable to an input buffer, comprising:
sensing a first noise current generated by a first bias current source at an output terminal of a first follower by a noise sensor;
converting the first noise current into a noise cancellation current via a subtractor; and
cancelling a noise generated by the first noise current by the noise cancellation current.

22. The noise cancellation method of claim 21, wherein a step of sensing the first noise current generated by the first bias current source at the output terminal of the first follower by the noise sensor, and a step of converting the first noise current into the noise cancellation current via the subtractor further comprise following steps respectively:
sensing the first noise current by the noise sensor to generate a first voltage; and
converting the first voltage into a noise cancellation current by the subtractor.

23. The noise cancellation method of claim 22, wherein a step of converting the first noise current into the noise cancellation current via the subtractor further comprises a following step:
generating a noise cancellation voltage at an output terminal of the subtractor via the noise cancellation current to cancel a first noise voltage at the output terminal of the first follower generated the first noise current.

24. The noise cancellation method of claim 21, further comprising following steps:
sensing a second noise current generated by a second bias current source at an output terminal of the subtractor by the noise sensor;
converting the second noise current into a noise suppression current by the subtractor; and
suppressing a noise generated by the second noise current via the noise suppression current.

25. The noise cancellation method of claim 24, wherein a step of sensing the second noise current generated by the second bias current source at the output terminal of the subtractor by the noise sensor, and a step of converting the second noise current into the noise suppression current by the subtractor further comprising following steps respectively:
sensing the second noise current by the noise sensor to generate a second voltage; and
converting the second voltage into a noise suppression current by the subtractor.

26. The noise cancellation method of claim 25, wherein a step of converting the second voltage into the noise suppression current by the subtractor further comprises a following step:
generating a noise suppression voltage at the output terminal of the subtractor via the noise suppression current to suppress a second noise voltage at the output terminal of the subtractor generated by the second noise current.

27. The noise cancellation method of claim 21, wherein the noise sensor comprises a first impedance and a second impedance coupled to the first impedance in series.

28. The noise cancellation method of claim 21, wherein the subtractor comprises a second follower and a transconductor.

29. The noise cancellation method of claim 21, wherein the first follower and the second follower are emitter followers or source followers.
